(19) United States
(12) Patent Application Publication
(10) Pub. No.: US 2024/0186260 A1
(43) Pub. Date: Jun. 6, 2024

(54) SEMICONDUCTOR DEVICE

(71) Applicant: LX SEMICON CO., LTD., Daejeon (KR)

(72) Inventor: Myeong Woo OH, Daejeon (KR)

(73) Assignee: LX SEMICON CO., LTD., Daejeon (KR)

(21) Appl. No.: 18/529,578

(22) Filed: Dec. 5, 2023

(30) Foreign Application Priority Data
Dec. 6, 2022 (KR) 10-2022-0168324
Nov. 8, 2023 (KR) 10-2023-0153306

(51) Int. Cl. H01L 23/544; H01L 23/528

(52) U.S. Cl. CPC H01L 23/544; H01L 23/5286; H01L 2223/54426

(57) ABSTRACT

A semiconductor device can comprise a core area comprising a cell array, a pad area surrounding the core area, a plurality of power lines on the pad area, and a plurality of alignment marks on the pad area. Each of the plurality of alignment marks can be electrically connected to one power line among the plurality of power lines.

### CROSS-REFERENCE TO RELATED APPLICATIONS

The present application claims the benefits of priority to Korean Patent Application No. 10-2022-0168324, filed on Dec. 6, 2022 and Korean Patent Application No. 10-2023-0153306, filed on Nov. 8, 2023 in the Republic of Korea, the entire contents of which are hereby expressly incorporated by reference into the present application

### BACKGROUND OF THE DISCLOSURE

### Field

The embodiment relates to a semiconductor device.

### Discussion of the Related Art

A semiconductor device is widely used to process, control, manage or store information or signals.

After a plurality of semiconductor devices are manufactured on a wafer by performing a typical semiconductor process, the wafer is cut so that the plurality of semiconductor devices are separated from each other. At this time, an alignment mark is formed to identify a reference position for distinguishing each of the plurality of semiconductor devices.

The semiconductor device includes a core area including a cell array and a pad area where power line for supplying power to the cell array is arranged. Alignment marks are located in the pad area.

In the existing pad area, the power line is not disposed in the area where the alignment mark is formed to avoid electrical short circuit with the alignment mark such that the power line can be electrically disconnected. Accordingly, the power line does not contribute to the reduction of resistance, which increases the resistance of the power line provided in the semiconductor device, resulting in increased power consumption due to current loss. In order to reduce the increased resistance, the power line must be formed on another insulating layer, which increases the number of processes and material costs and complicates the structure.

### SUMMARY OF THE DISCLOSURE

An object of the embodiment is to solve the foregoing and other problems.

Another purpose of the embodiment is to provide a semiconductor device that does not require additional power line, thereby reducing the number of processes and material costs and simplifying the structure.

Another object of the embodiment is to provide a semiconductor device capable of reducing power consumption.

The technical problem of the embodiment is not limited to those described in this section, and include those that can be grasped through the description of the invention.

According to a first aspect of the embodiment to achieve the above or other objects, a semiconductor device, comprising: a core area comprising a cell array: a pad area surrounding the core area: a plurality of power lines on the pad area: and a plurality of alignment marks on the pad area, wherein each of the plurality of alignment marks are configured to be electrically connected to one power line among the plurality of power lines.

The alignment mark can be disposed in at least one or more corner area of the pad area.

The alignment mark can be disposed on the one power line among the plurality of power lines and can be configured to be electrically connected to the one power line.

The alignment mark can be disposed on the plurality of power lines and can be electrically connected to one power line of the plurality of power lines.

The alignment mark can comprise a power pad, a pad open, and a bump.

The semiconductor device can comprise an insulating layer comprising the pad open. The power pad can be a part of one power line among the plurality of power lines, the pad open can be located on the power pad, and the bump can contact the power pad through the pad open. Each of the plurality of power lines can comprise a first power line disposed adjacent to the core area: and a second power line disposed farther from the core area than the first power line. The alignment mark can comprise a power pad, a pad open, and a bump.

At least one or more corner area of the pad area can comprise a disconnection area where the second power line is disconnected, and the power pad can extend from the first power line to the disconnection area.

At least one or more corner area of the pad area can comprise a disconnection area where the first power line is disconnected, and the power pad can extend from the second power line to the disconnection area.

The semiconductor device can comprise a first power pad configured to connect the first power line in at least one or more corner area of the pad area from a first direction to a second direction perpendicular to the first direction: and a second power pad configured to connect the second power line in the corner area from the first direction to the second direction. The pad open can be located on the first power pad, and the bump can contact the first power pad through the pad open.

The bump can be disposed on the first power pad and the second power pad.

The semiconductor device can comprise a first power pad configured to connect the first power line in at least one or more corner area of the pad area from a first direction to a second direction perpendicular to the first direction: and a second power pad configured to connect the second power line in the corner area from the first direction to the second direction. The pad open can be located on the second power pad, and the bump can contact the second power pad through the pad open.

The bump can be disposed on the first power pad and the second power pad.

According to a second aspect of the embodiment to achieve the above or other objects, a semiconductor device, comprising: a core area comprising a cell area: a pad area surrounding the core area: a plurality of insulating layers in the pad area: a plurality of power lines between the plurality of insulating layers: and a plurality of alignment marks on the uppermost power line among the plurality of power lines, wherein the uppermost power line comprises: a first power line disposed adjacent to the core area; and a second power line disposed farther from the core area than the first power line, and wherein each of the plurality of alignment marks is configured to be electrically connected to one of the first power line and/or the second power line.

Each of the plurality of insulating layers can comprise a via, and the plurality of power lines can be electrically connected to each other through the plurality of vias.

The alignment mark can be disposed in at least one or more corner area of the pad area.

The alignment mark can be disposed on one of the first power lines and the second power line, and is configured to be electrically connected to the one power line.

The alignment mark can be disposed on the first power line and the second power line, and be electrically connected to one of the first power line and/or the second power line.

The alignment mark can comprise a power pad, a pad open, and a bump.

The alignment mark can comprise a power pad, a pad open, and a bump. The uppermost insulating layer among the plurality of insulating layers can comprise the pad open. The power pad can be a part of one of the first power line and the second power line. The pad open can be located on the power pad, and the bump can contact the power pad through the pad open.

The effects of the semiconductor device according to the embodiment will be described as follows.

According to at least one of the embodiments, electrical disconnection of power line can be prevented using alignment marks. That is, the bumps of the alignment marks can be electrically connected to the power pads, which are parts of the power lines, through pad opens.

Accordingly, the resistances of the power lines can be reduced, thereby reducing power consumption. Additionally, an increase in the number of processes and material costs can be prevented and the structure can be simplified. The alignment marks can be used for film level routing (FLR) in power bumps.

A further scope of applicability of the embodiment will become apparent from the detailed description that follows. However, since various changes and modifications within the spirit and scope of the embodiment can be clearly understood by those skilled in the art, it should be understood that the detailed description and specific embodiment, such as preferred embodiment, are given by way of example only.

### BRIEF DESCRIPTION OF THE DRAWINGS

FIG. 1 shows a plurality of semiconductor devices being manufactured on a wafer.

FIG. 2 is a plan view schematically showing a semiconductor device according to an embodiment.

FIG. 3 shows a cross-sectional view taken along line A-A′ of the semiconductor device according to the embodiment of FIG. 1.

FIG. 4 is a plan view showing a corner area of a pad area of a semiconductor device according to the first embodiment.

FIG. 5A is a cross-sectional view taken along line B-B′ at the corner area of the pad area of the semiconductor device according to the first embodiment of FIG. 4.

FIG. 5B is a cross-sectional view taken along line C-C′ at the corner area of the pad area of the semiconductor device according to the first embodiment of FIG. 4.

FIG. 6 is a plan view of a corner area of a pad area of a semiconductor device according to the second embodiment.

FIG. 7A is a cross-sectional view taken along line D-D′ at the corner area of the pad area of the semiconductor device according to the second embodiment of FIG. 6.

FIG. 7B is a cross-sectional view taken along line E-E′ in the corner area 102 of the pad area of the semiconductor device according to the second embodiment of FIG. 6.

FIG. 8 is a plan view showing a corner area of a pad area of a semiconductor device according to the third embodiment.

FIG. 9A is a cross-sectional view taken along line F-F′ at the corner area of the pad area of the semiconductor device according to the third embodiment of FIG. 8.

FIG. 9B is a cross-sectional view taken along line G-G′ at the corner area of the pad area of the semiconductor device according to the third embodiment of FIG. 8.

FIG. 10 is a plan view showing a corner area of a pad area of a semiconductor device according to the fourth embodiment.

FIG. 11A is a cross-sectional view taken along line H-H′ at the corner area of the pad area of the semiconductor device according to the fourth embodiment of FIG. 10.

FIG. 11B is a cross-sectional view taken along line II′ at the edge of the pad area of the semiconductor device according to the fourth embodiment of FIG. 10.

The sizes, shapes, dimensions, etc. of elements shown in the drawings can differ from actual ones. In addition, even if the same elements are shown in different sizes, shapes, dimensions, etc. between the drawings, this is only an example on the drawing, and the same elements have the same sizes, shapes, dimensions, etc. between the drawings.

### DETAILED DESCRIPTION OF EMBODIMENTS

Hereinafter, the embodiment disclosed in this specification will be described in detail with reference to the accompanying drawings, but the same or similar elements are given the same reference numerals regardless of reference numerals, and redundant descriptions thereof will be omitted. The suffixes ‘module’ and ‘unit’ for the elements used in the following descriptions are given or used interchangeably in consideration of ease of writing the specification, and do not themselves have a meaning or role that is distinct from each other. In addition, the accompanying drawings are for easy understanding of the embodiment disclosed in this specification, and the technical idea disclosed in this specification is not limited by the accompanying drawings. Also, when an element such as a layer, area or substrate is referred to as being ‘on’ another element, this means that there can be directly on the other element or be other intermediate elements therebetween.

The semiconductor device of the embodiment can be used to process, control, manage, or store information or signals. Additionally, the semiconductor device of the embodiment can be used to convert a direct current voltage to an alternating current voltage, an alternating voltage to a direct current voltage, or a direct current voltage to another direct current voltage. That is, the semiconductor device of the embodiment can be used as a processing element, a control element, a memory element, a switching element, etc. The semiconductor device of the embodiment can comprise a transistor for electrostatic discharge (ESD) diode. The semiconductor device of the embodiment can comprise a driving transistor.

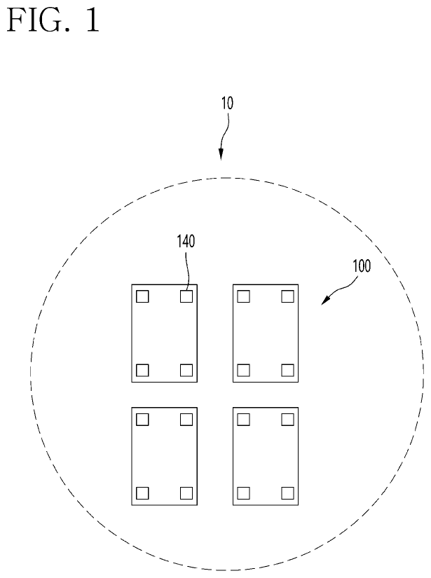

FIG. 1 shows a plurality of semiconductor devices being manufactured on a wafer.

As shown in FIG. 1, the semiconductor device 100 of the embodiment can be manufactured by performing a series of semiconductor processes on the wafer 10. That is, by repeatedly performing a series of semiconductor processes, such as a deposition process, an etching process, and a cleaning process, on the wafer 10, a plurality of semiconductor devices 100 having various functions can be manufactured. The plurality of semiconductor devices 100 can be manufactured simultaneously on the wafer 10.

A post-process, that is, a cutting process, can be performed to separate the plurality of semiconductor devices 100 into the unit of chip. The plurality of semiconductor devices 100 on the wafer 10 can be spaced apart from each other. By cutting the wafer 10 to correspond to a preset semiconductor size, the plurality of semiconductor devices 100 can be separated. Before performing the cutting process, the position or size of each of the plurality of semiconductor devices 100 can be identified. To this end, a plurality of alignment marks 140 can be formed on the semiconductor device 100 by performing a series of semiconductor processes. Although three alignment marks 140 are shown in the drawing, fewer or more alignment marks can be provided. Therefore, an alignment process is performed using the alignment mark 140 so that the wafer can be cut to match the size of the plurality of semiconductor devices 100, so that the position or size of each of the plurality of semiconductor devices 100 can be identified.

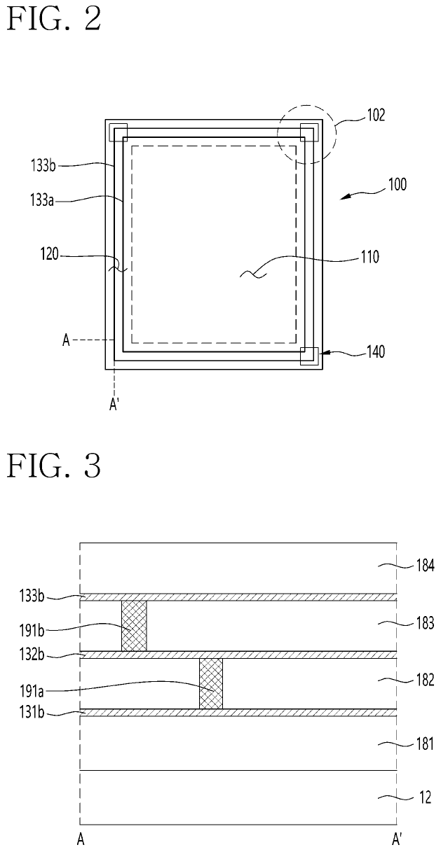

FIG. 2 is a plan view schematically showing a semiconductor device according to an embodiment. FIG. 3 shows a cross-sectional view taken along line A-A′ of the semiconductor device according to the embodiment of FIG. 1.

Referring to FIGS. 2 and 3, the semiconductor device 100 according to an embodiment can comprise a core area 110 and a pad area 120 surrounding the core area 110. The core area 110 can comprise a cell array. For example, the cell array can be formed by forming a plurality of transistors on the wafer 10 in a preset arrangement. The transistor can be, for example, a MOSFET, but is not limited thereto. A plurality of capacitors or other electronic devices can be provided in the core area 110.

The semiconductor device 100 according to the embodiment can comprise a plurality of insulating layers 181 to 184 and a plurality of power lines 131b, 132b, 133a, and 133b. The plurality of insulating layers 181 to 184 can be disposed on a substrate 12. The substrate 12 can be wafer 10 shown in FIG. 1. Alternatively, a separate substrate can be provided as the substrate 12 after the wafer 10 can be removed through a post-process. The plurality of insulating layers 181 to 184 can be vertically stacked.

The plurality of power lines 131b, 132b, 133a, and 133b can be disposed in the pad area 120. For example, the plurality of power lines 131b, 132b, 133a, and 133b can each be disposed in the pad area 120 to surround the core area 110, but is not limited thereto.

The plurality of power lines 131b, 132b, 133a, and 133b can be disposed on each insulating layer 181 to 183. For example, The plurality of power lines 131b, 132b, 133a, and 133b can be disposed on the first insulating layer 181, the second insulating layer 182, and the third insulating layer 183, respectively. The plurality of power lines 131b, 132b, 133a, and 133b can comprise, for example, the first power line 133a and the second power lines 131b, 132b, and 133b, but are not limited thereto. A first voltage can be supplied through the first power line 133a, and a second voltage smaller than the first voltage can be supplied through the second power lines 131b, 132b, and 133b, but is not limited thereto.

For example, the plurality of first power lines 133a can be vertically overlapped between the plurality of insulating layers 181 to 184, but is not limited thereto. For example, the plurality of second power lines 131b, 132b, and 133b can be vertically overlapped between the plurality of insulating layers 181 to 184, but is not limited thereto.

The plurality of power lines 131b, 132b, 133a, and 133b can be electrically connected to each other through vias 191a and 191b formed in the plurality of insulating layers 181 to 183. For example, the plurality of first power lines 133a disposed between the plurality of insulating layers 181 to 184 can be electrically connected to each other through a plurality of vias, so that the resistance of the first power line 133a can be reduced. The plurality of second power lines 131b, 132b, and 133b can be electrically connected to each other through the plurality of vias 191a and 191b, so that the resistance of the second power lines 131b, 132b, and 133b can be reduced.

In the drawing, all of the plurality of second power lines 131b, 132b, and 133b disposed between the plurality of insulating layers 181 to 184 are shown to be electrically connected, but is not limited thereto. Likewise, the first power line on one of the plurality of first power lines 133a disposed between the plurality of insulating layers 181 to 184 may not be electrically connected to the first power line on the other insulating layer.

Meanwhile, the semiconductor device 100 according to the embodiment can comprise a plurality of alignment marks 140. The plurality of alignment marks 140 can be disposed in the pad area 120. As shown in FIG. 2, the alignment mark 140 can be disposed in at least one or more corner area 102, but is not limited thereto. Although three alignment marks 140 are shown in the drawing, two alignment marks or four or more alignment marks can be provided. In the drawing, the alignment mark 140 is shown as having a square shape, but it can have a different shape.

The alignment mark 140 can be disposed on the uppermost power lines 133a and 133b among the plurality of power lines 131b, 132b, 133a and 133b.

As shown in FIG. 2, the first power line 133a and the second power line 133b constituting the uppermost power line can be disposed in the pad area 120, and the alignment marks 140 can be disposed on the first power line 133a and the second power line 133b in the corner area 102.

The first power line 133a can be disposed adjacent to the core area 110. The first power line 133a can be disposed to surround the core area 110, but is not limited thereto. The second power line 133b can be disposed farther from the core area 110 than the first power line 133a. That is, the second power line 133b can be disposed adjacent to the edge of the semiconductor device 100, for example, the outer edge of the pad area 120. The second power line 133b can be disposed to surround the first power line 133a.

The alignment mark 140 can be electrically connected to one of the first power line 133a and/or the second power line 133b. In this instance, even if the alignment mark 140 is disposed, since the alignment mark 140 is connected to the one power line, disconnection of the one power line can be prevented.

When the alignment mark 140 is not connected to the first power line 133a or the second power line 133b, the first power line 133a or the second power line 133b can be electrically disconnected. In this case, the first power line 133a or the second power line 133b on the third insulating layer 183 does not contribute to reducing the resistance of the power line, so that the resistance of the power line can increase. Thus, power consumption can increase due to current loss through the first power line 133a or the second power line 133b. In addition, in order to prevent an increase in resistance, the first power line and the second power line must be additionally formed on a separate insulating layer, for example, the fourth insulating layer 184, thus increasing the number of processes and material costs and complicating the structure.

However, according to the embodiment, the alignment mark 140 can be timely connected to one of the first power line 133a and/or the second power line 133b constituting the uppermost power line. In this case, as the first power line 133a or the second power line 133b on the third insulating layer 183 contributes to reducing the resistance of the power line, the resistance of the power line can be reduced, thereby reducing power consumption. In addition, there is no need to form a separate insulating layer or another first and second power line, so that the number of processes and material costs can be reduced and the structure can be simplified.

### First Embodiment

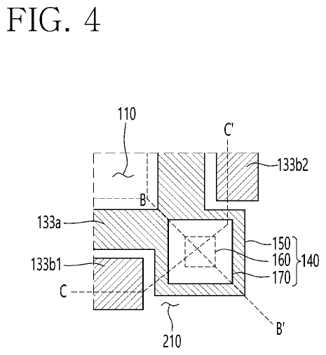

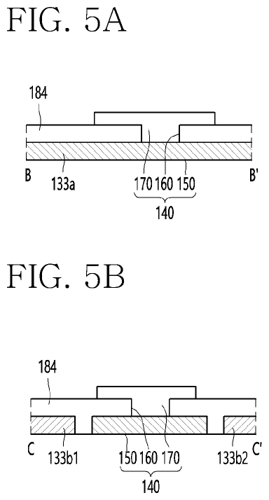

FIG. 4 is a plan view showing a corner area of a pad area of a semiconductor device according to the first embodiment. FIG. 5A is a cross-sectional view taken along line B-B′ at a corner area of the pad area of the semiconductor device according to the first embodiment of FIG. 4. FIG. 5B is a cross-sectional view taken along line C-C′ in the corner area 102 of the pad area 120 of the semiconductor device according to the first embodiment of FIG. 4.

As shown in FIGS. 2, 4, 5A, and 5B, the alignment mark 140 can be disposed in the corner area 102 of the pad area 120. The alignment mark 140 can comprise a power pad 150, a pad open 160, and a bump 170. The power pad 150 can be made of a material with excellent electrical conductivity, such as metal. The bump 170 can be made of a material with excellent reflective properties. For example, the power pad 150 can be made of copper (Cu), etc., and the bump 170 can be made of gold (Au), etc., but is not limited thereto.

The power pad 150 can be a part of one of the plurality of power lines 131b, 132b, 133a, and 133b. The plurality of power lines 131b, 132b, 133a, and 133b can comprise the first power line 133a and the second power line 133b, but more power lines can be provided. In this instance, the power pad 150 can be a part of the first power line 133a.

The second power line 133b can comprise a second-first power line 133b1 and a second-second power line 133b2 that are separated from each other.

The corner area 102 can comprise a disconnection area 210 where the second power line 133b is disconnected. Here, disconnection can mean not only electrical disconnection but also physical separation. For example, the second-first power line 133b1 can be disposed along a first direction, for example, the horizontal direction, and can be cut at the disconnection area 210 of the corner area 102. For example, the second-second power line 133b2 can be disposed along a second direction, for example, a vertical direction, and can be cut in the disconnection area 210 of the corner area 102. Accordingly, not only the second-first power line 133b1 but also that the second-second power line 133b2 may not be disposed in the disconnection area 210.

The power pad 150 can be disposed in the disconnection area 210 of the corner area 102. The power pad 150 can extend from the first power line 133a to the disconnection area 210. The first power line 133a can be disposed along a first direction and along a second direction in the corner area 102. In addition, the first power line 133a can be disposed in an area where the first direction and the second direction intersect. The power pad 150 can extend diagonally from one side of the first power line 133a disposed in the intersection area and can be disposed in the disconnection area 210. In this instance, the power pad 150 can be disposed between the second-first power line 133b1 and the second-second power line 133b2 in the disconnection area 210. The power pad 150 can be spaced apart from the cut end of the second-first power line 133b1 and the cut end of the second-second power line 133b2, respectively, in the disconnection area 210, so that electrical short circuit between the first power line 133a and the second power line 133b can be prevented. A fourth insulating layer (184 in FIG. 3) can be disposed between the first power line 133a and the second power line 133b or on the first power line 133a and the second power line 133b. An insulating layer made of a different material from the fourth insulating layer 184 can be disposed between the first power line 133a and the second power line 133b, but this is not limited thereto.

Meanwhile, the fourth insulating layer 184 can comprise a pad open 160 in the corner area 102. The fourth insulating layer 184 can be removed to expose the power pad 150, thereby forming the pad open 160. In the drawing, the pad open 160 has a square shape, but it can have another shape, for example, a slit shape. The diameter of the pad open 160 can be at least 10 micrometers or more. If the diameter of the pad open 160 is less than 10 micrometers, it can be difficult to identify the alignment mark 140 using an optical device. The pad open 160 can be referred to as an opening or slit.

The pad open 160 can be located in the disconnection area 210. The pad open 160 can be located on the power pad 150 extending from the first power line 133a.

In an embodiment, the bump 170 can be disposed on the same layer as a bump for external terminal connection or a test bump. That is, the bump 170 for alignment mark, the bump for external terminal connection, a test bump, etc. can be formed on the fourth insulating layer 184. When the bump for external terminal connection is manufactured as an integrated circuit, it can be connected to an external terminal made of an externally exposed lead frame or solder. The test bump can be contacted with a test terminal such as a probe to test the electrical characteristics of the cell array provided in the core area 110. Accordingly, since there is no need to additionally form the bump 170 for alignment mark, material costs can be reduced and the number of processes can be reduced.

The bump 170 can be electrically connected to the power pad 150 extending from the first power line 133a through the pad open 160. The bump 170 can be disposed on the power pad 150 extending from the first power line 133a. The bump 170 can contact an upper surface of the power pad 150 extending from the first power line 133a through the pad open 160. The size of the bump 170 can be greater than the size of the pad open 160. A portion of the bump 170 can be disposed on the pad open 160 and another portion of the bump 170 can be disposed on an upper surface of the fourth insulating layer 184 around the pad open 160. A portion of the bump 170 can contact the upper surface of the power pad 150 extending from the first power line 133a through the pad open 160, so that the bump 170 and the power pad 150 can be electrically connected.

When the pad open 160 is omitted and the bump 170 is disposed only on the upper surface of the fourth insulating layer 184, not only the bump 170 for alignment mark but also that the bump for external terminal connection and the test bump can be disposed only on the upper surface of the fourth insulating layer 184. In this instance, the fixation of the bumps 170 can deteriorate and the corresponding bumps 170 can be separated during the alignment process, external terminal connection process, or test process.

However, according to the embodiment, the bump 170 can be in contact with the power pad 150 extending from the first power line 133a through the pad open 160 and can be disposed on the upper surface of the fourth insulating layer 184 around the pad open 160, the fixation of the bump 170 can be strengthened and reliability can be improved. According to an embodiment, electrical disconnection of the first power line 133a can be prevented in the corner area 102 of the pad area 120 using the alignment mark 140 including the power pad 150, pad open 160, and bump 170. Thus, the resistance of the first power line 133a can be reduced, so that power consumption can be reduced. Additionally, an increase in the number of processes and material costs can be prevented and the structure can be simplified.

### Second Embodiment

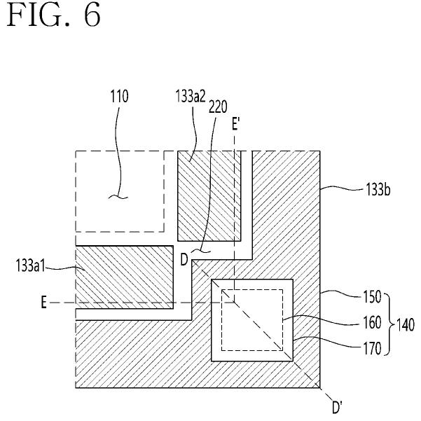

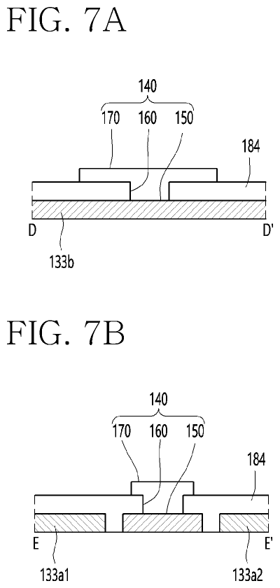

FIG. 6 is a plan view showing a corner area of a pad area of a semiconductor device according to the second embodiment. FIG. 7A is a cross-sectional view taken along line D-D′ at a corner area of the pad area of the semiconductor device according to the second embodiment of FIG. 6. FIG. 7B is a cross-sectional view taken along line E-E′ at the edge of the pad area of the semiconductor device according to the second embodiment of FIG. 6.

In the first embodiment (FIGS. 4, 5A, and 5B), the alignment mark 140 can be electrically connected to the first power line 133a, while in the second embodiment, the alignment mark 140 can be electrically connected to the second power line 133b. Descriptions omitted in the second embodiment below can be easily implemented from the description of the first embodiment (FIGS. 4, 5A, and 5B).

As shown in FIGS. 2, 4, 5A, and 5B, the alignment mark 140 can be disposed in the corner area 102 of the pad area 120. The alignment mark 140 can comprise a power pad 150, a pad open 160, and a bump 170.

The power pad 150 can be a part of one of a plurality of power lines 131b, 132b, 133a, and 133b. For example, the plurality of power lines 131b, 132b, 133a, and 133b can comprise the first power line 133a and the second power line 133b, but more power lines can be provided. In this instance, the power pad 150 can be a part of the second power line 133b.

The first power line 133a can comprise a first-first power line 133a1 and a first-second power line 133a2 that are separated from each other.

The corner area 102 can comprise a disconnection area 220 where the first power line 133a is disconnected. For example, the first-first power line 133a1 can be disposed along a first direction, for example, the horizontal direction, and can be cut at the disconnection area 220 of the corner area 102. For example, the first-second power line 133a2 can be disposed along a second direction, for example, a vertical direction, and can be cut in the disconnection area 220 of the corner area 102. Accordingly, not only the first-first power line 133a1 but also the first-second power line 133a2 may not be disposed in the disconnection area 220.

The power pad 150 can be disposed in the disconnection area 220 of the corner area 102. The power pad 150 can extend from the second power line 133b to the disconnection area 220. The second power line 133b can be disposed along a first direction and along a second direction in the corner area 102. In addition, the second power line 133b can be disposed in an area where the first direction and the second direction intersect. The power pad 150 can extend diagonally from one side of the second power line 133b disposed in the intersection area and can be disposed in the disconnection area 220. In this instance, the power pad 150 can be disposed between the first-first power line 133a1 and the first-second power line 133a2 in the disconnection area 220. The power pad 150 can be spaced apart from the cut end of the first-first power line 133a1 and the cut end of the first-second power line 133a2, respectively, in the disconnection area 220, so that an electrical short circuit between the first power line 133a and the second power line 133b can be prevented.

Meanwhile, the fourth insulating layer 184 can comprise a pad open 160 in the corner area 102. The fourth insulating layer 184 can be removed to expose the power pad 150, thereby forming a pad open 160.

The pad open 160 can be located in the disconnection area 220. The pad open 160 can be located on the power pad 150 extending from the second power line 133b.

In an embodiment, the bump 170 can be disposed on the same layer as the bump for external terminal connection or the test bump. That is, a bump 170 for alignment mark, a bump for external terminal connection, a test bump, etc. can be formed on the fourth insulating layer 184. Accordingly, since there is no need to form a separate bump for the bump 170 for alignment mark, material costs can be reduced and the number of processes can be reduced.

The bump 170 can be electrically connected to the power pad 150 extending from the second power line 133b through the pad open 160. The bump 170 can be disposed on the power pad 150 extending from the second power line 133b. The bump 170 can contact the upper surface of the power pad 150 extending from the second power line 133b through the pad open 160. The size of the bump 170 can be greater than the size of the pad open 160. A portion of the bump 170 can be disposed on the pad open 160 and another portion of the bump 170 can be disposed on the upper surface of the fourth insulating layer 184 around the pad open 160. A portion of the bump 170 can be electrically connected between the bump 170 and the power pad 150 by contacting the upper surface of the power pad 150 extending from the second power line 133b through the pad open 160.

When the pad open 160 is omitted and the bump 170 is disposed only on the upper surface of the fourth insulating layer 184, not only the alignment mark bump 170 but also the external terminal connection bump and the test bump can be also disposed only on the upper surface of the fourth insulating layer 184. In this case, the fixation of the bumps 170 can deteriorate and the corresponding bumps 170 can be separated during the alignment process, external terminal connection process, or test process.

However, according to the embodiment, the bump 170 can be in contact with the power pad 150 extending from the second power line 133b through the pad open 160 and can be disposed on the upper surface of the fourth insulating layer 184 around the pad open 160, the fixation of the bump 170 can be strengthened and reliability can be improved. According to an embodiment, electrical disconnection of the second power line 133b can be prevented in the corner area 102 of the pad area 120 using the alignment mark 140 including the power pad 150, pad open 160, and bump 170. Thus, the resistance of the second power line 133b can be reduced, so that power consumption can be reduced. Additionally, an increase in the number of processes and material costs can be prevented and the structure can be simplified.

Meanwhile, in the first embodiment (FIGS. 4, 5A and 5B) or the second embodiment (FIGS. 6, 7A and 7B), the disconnection area 210 or 220 in which the first power line 133a or the second power line 133b are disconnected from each other can be located in the corner area 102.

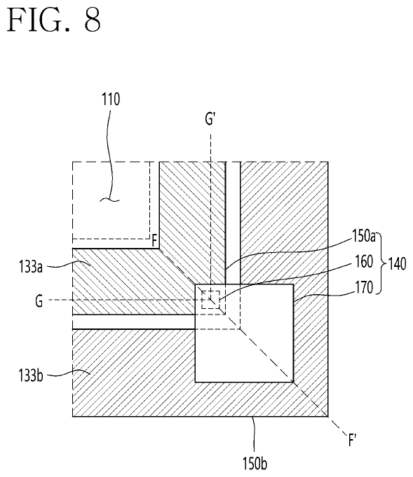

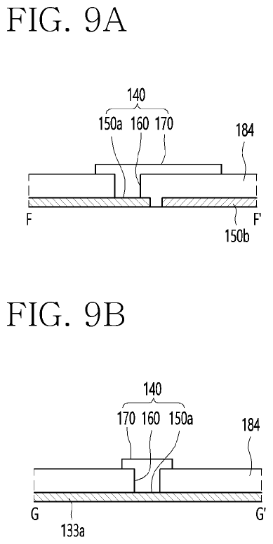

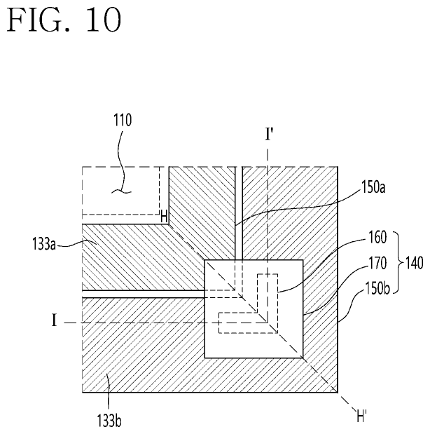

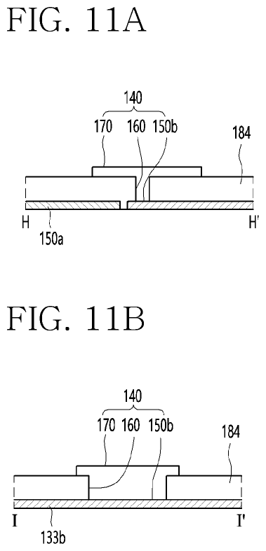

On the other hand, in the third embodiment (FIGS. 8, 9A and 9B) or the fourth embodiment (FIGS. 10, 11A and 11B) to be described below, the disconnection area can be omitted. That is, in the third embodiment (FIGS. 8, 9A and 9B) or the fourth embodiment (FIGS. 10, 11A and 11B), the first power line 133a or the second power line 133b can be disposed in the corner area 102 without being disconnected from each other.

### Third Embodiment

FIG. 8 is a plan view showing a corner area of a pad area of a semiconductor device according to the third embodiment. FIG. 9A is a cross-sectional view taken along line F-F′ at a corner area of the pad area of the semiconductor device according to the third embodiment of FIG. 8. FIG. 9B is a cross-sectional view taken along line G-G′ at the corner area of the pad area of the semiconductor device according to the third embodiment of FIG. 8.

As shown in FIGS. 2, 8, 9A, and 9B, the alignment mark 140 can be electrically connected to the first power pad 150a in the corner area 102.

The first power pad 150a and the second power pad 150b can be disposed in the corner area 102. The first power pad 150a and the second power pad 150b can have shapes that correspond to each other.

The first power pad 150a can be a connecting member that connects the first power line 133a in the corner area 102 from the first direction to the second direction. Accordingly, the first power pad 150a can be formed integrally with the first power line 133a. The second power pad 150b can be a connecting member that connects the second power line 133b in the corner area 102 from the first direction to the second direction. Accordingly, the second power pad 150b can be formed integrally with the second power line 133b. The first direction and the second direction can be perpendicular to each other, but are not limited thereto.

The first power line 133a may not be disconnected by the first power pad 150a, and the second power line 133b may not be disconnected by the second power pad 150b. Accordingly, the number of processes and material costs due to additional formation of an additional insulating layer or each of the first power line 133a and the second power line 133b to meet the preset resistance can be reduced and the structure can be simplified.

The width of the first power pad 150a can be the same as the width of the first power line 133a, but is not limited thereto. The width of the second power pad 150b can be the same as the width of the second power line 133b, but is not limited thereto. The first power pad 150a and the second power pad 150b can each have a bent shape. The first power pad 150 and the second power pad 150b can each have an “L” shape, but is not limited thereto. For example, the first power pad 150a and the second power pad 150b can each have a shape bent at 90 degrees, but is not limited thereto.

The alignment mark 140 can comprise a power pad 150, a pad open 160, and a bump 170.

The power pad 150 can be a first power pad 150a formed integrally with the first power line 133a. The pad open 160 can be located on the first power pad 150a.

The pad open 160 can be located on the first power pad 150a adjacent to the second power pad 150b. The pad open 160 can be formed in the fourth insulating layer 184.

The bump 170 can be located on pad open 160. The bump 170 can be disposed on the first power pad 150a. The bump 170 can have a square shape, but is not limited thereto. The bump 170 can contact the first power pad 150a through the pad open 160. The bump 170 can be disposed on the second power pad 150b. That is, the bump 170 can be disposed on the first power pad 150a and the second power pad 150b. The bump 170 can be disposed on the first power pad 150a and extend diagonally to be disposed on the second power pad 150b. As the bump 170 can be in contact with the upper surface of the fourth insulating layer 184 and the upper surface of the first power pad 150a through the pad open 160, the fixation of the bump 170 can be strengthened and reliability can be improved.

According to an embodiment, the bump 170 of the alignment mark 140 can be electrically connected to the first power line 133a through the first power pad 150a in the corner area 102.

In addition, the bump 170 of the alignment mark 140 can be electrically connected to the first power pad 150a formed integrally with the first power line 133a through the pad open 160, and may not be electrically connected to the second power pad 150b formed integrally with the second power line 133b. Accordingly, while the alignment mark 140 can be disposed in the corner area 102, the bump 170 of the alignment mark 140 can be not connected to the second power line 133b but can be connected to the first power line 133a, so that both the first power line 133a and the second power line 133b may not be disconnected. As shown in FIGS. 2, 3, and 8, the second power lines 131b and 132b can be electrically connected to each other through the via 191a. Additionally, since there is no alignment mark on the second power lines 131b and 132b, the second power lines 131b and 132b may be not disconnected. In addition, as shown in FIGS. 8 and 9, As described above, the second power line 133b, which can be electrically connected to the second power line 132b through the via 191b, may not be disconnected through the second power pad 150b disposed below the alignment mark 140 and may not be electrically connected to the bump 170 of the alignment mark 140, so that it can be used as a power line to supply a second voltage. Therefore, since all three power lines (131b, 132b, 133b) can be used as power lines for supplying the second voltage, the resistance of the three power lines (131b, 132b, 133b) can be reduced, thereby reducing power consumption. In addition, the alignment process can be performed through the alignment mark 140, and there is no need to add additional layers. Thus, complex technical effects can be obtained in which the thickness or size of the semiconductor device 100 is reduced, the structure is simplified, and the number of processes and material costs are reduced.

### Fourth Embodiment

FIG. 10 is a plan view showing a corner area of a pad area of a semiconductor device according to the fourth embodiment. FIG. 11A is a cross-sectional view taken along line H-H′ at a corner area of the pad area of the semiconductor device according to the fourth embodiment of FIG. 10. FIG. 11B is a cross-sectional view taken along line II′ at a corner area of the pad area of the semiconductor device according to the fourth embodiment of FIG. 10.

In the fourth embodiment, unlike the third embodiment, the alignment mark 140 can be electrically connected to the second power pad 150b in the corner area 102.

As shown in FIGS. 2, 8, 9A, and 9B, the alignment mark 140 can be electrically connected to the first power pad 150a in the corner area 102.

The first power pad 150a and the second power pad 150b can be disposed in the corner area 102. The first power pad 150a and the second power pad 150b can have shapes that correspond to each other.

The first power pad 150a can be formed integrally with the first power line 133a, and the second power pad 150b can be formed integrally with the second power line 133b. The first power line 133a can be electrically connected to the corner area 102 without being disconnected by the first power pad 150a. The second power line 133b can be electrically connected without being disconnected in the corner area 102 by the second power pad 150b.

The first power line 133a may not be disconnected by the first power pad 150a, and the second power line 133b may not be disconnected by the second power pad 150b. Accordingly, the number of processes and material costs due to additional formation of an additional insulating layer or each of the first power line 133a and the second power line 133b to meet the preset resistance can be reduced and the structure can be simplified.

The alignment mark 140 can comprise a power pad 150, a pad open 160, and a bump 170.

The power pad 150 can be a second power pad 150b formed integrally with the second power line 133b. The pad open 160 can be located on the second power pad 150b.

The pad open 160 can be located on the second power pad 150b adjacent to the first power pad 150a. The pad open 160 can be formed in the fourth insulating layer 184. The pad open 160 can have a shape corresponding to the shape of the second power pad 150b. The pad open 160 can have a bent shape. The width of the minor axis of the pad open 160 can be at least 10 micrometers or more.

The bump 170 can be located on pad open 160. The bump 170 can be disposed on the second power pad 150b. The bump 170 can contact the second power pad 150b through the pad open 160. The bump 170 can be disposed on the first power pad 150a. That is, the bump 170 can be disposed on the first power pad 150a and the second power pad 150b. The bump 170 can be disposed on the second power pad 150b and extend diagonally to be disposed on the first power pad 150a. As the bump 170 can be in contact with the upper surface of the fourth insulating layer 184 and the upper surface of the second power pad 150b through the pad open 160, the fixation of the bump 170 can be strengthened and reliability can be improved.

According to an embodiment, the bump 170 of the alignment mark 140 can be electrically connected to the second power line 133b through the second power pad 150b in the corner area 102.

In addition, the bump 170 of the alignment mark 140 can be electrically connected to the second power pad 150b formed integrally with the second power line 133b through the pad open 160 and may not be electrically connected to the first power pad 150a formed integrally with the first power pad 133a. Accordingly, while the alignment mark 140 is disposed in the corner area 102, the bump 170 of the alignment mark 140 may be not connected to the first power line 133a but can be connected to the second power line 133b, so that both the first power line 133a and the second power line 133b may not be disconnected. As shown in FIGS. 2, 3, and 10, both the first power line 133a disposed on each of the first insulating layer 181 and the second insulating layer 182 as well as the first power line 133a disposed on the third insulating layer 183 can be used as power line to supply a first voltage, so that the resistance of the three power lines 133a can be reduced, thereby reducing power consumption. In addition, the alignment process can be performed through the alignment mark 140, and there is no need to add additional layers. Thus, complex technical effects can be obtained in which the thickness or size of the semiconductor device 100 is reduced, the structure is simplified, and the number of processes and material costs are reduced.

The above detailed description should not be construed as limiting in all respects and should be considered illustrative. The scope of the embodiment should be determined by reasonable interpretation of the appended claims, and all changes within the equivalent range of the embodiment are included in the scope of the embodiment.

What is claimed is:

1. A semiconductor device, comprising:
a core area comprising a cell array;
a pad area surrounding the core area;
a plurality of power lines on the pad area; and
a plurality of alignment marks on the pad area,
wherein each of the plurality of alignment marks are configured to be electrically connected to one power line among the plurality of power lines.

2. The semiconductor device of claim 1, wherein the alignment mark is disposed in at least one or more corner area of the pad area.

3. The semiconductor device of claim 1, wherein the alignment mark is disposed on the one power line among the plurality of power lines and is configured to be electrically connected to the one power line.

4. The semiconductor device of claim 1, wherein the alignment mark is disposed on the plurality of power lines and is configured to be electrically connected to one power line of the plurality of power lines.

5. The semiconductor device of claim 1, wherein the alignment mark comprises a power pad, a pad open, and a bump.

6. The semiconductor device of claim 5, comprising:
an insulating layer comprising the pad open,
wherein
the power pad is a part of one power line among the plurality of power lines,
the pad open is located on the power pad, and
the bump is configured to contact the power pad through the pad open.

7. The semiconductor device of claim 1, wherein each of the plurality of power lines comprises:
a first power line disposed adjacent to the core area; and
a second power line disposed farther from the core area than the first power line, and
wherein the alignment mark comprises a power pad, a pad open, and a bump.

8. The semiconductor device of claim 7, wherein
at least one or more corner area of the pad area comprises a disconnection area where the second power line is disconnected, and
the power pad is configured to extend from the first power line to the disconnection area.

9. The semiconductor device of claim 7, wherein
at least one or more corner area of the pad area comprises a disconnection area where the first power line is disconnected, and
the power pad is configured to extend from the second power line to the disconnection area.

10. The semiconductor device of claim 7, comprising:
a first power pad configured to connect the first power line in at least one or more corner area of the pad area from a first direction to a second direction perpendicular to the first direction; and
a second power pad configured to connect the second power line in the corner area from the first direction to the second direction,
wherein
the pad open is located on the first power pad, and
the bump is configured to contact the first power pad through the pad open.

11. The semiconductor device of claim 10, wherein the bump is disposed on the first power pad and the second power pad.

12. The semiconductor device of claim 7, comprising:
a first power pad configured to connect the first power line in at least one or more corner area of the pad area from a first direction to a second direction perpendicular to the first direction; and
a second power pad configured to connect the second power line in the corner area from the first direction to the second direction,
wherein
the pad open is located on the second power pad, and
the bump is configured to contact the second power pad through the pad open.

13. The semiconductor device of claim 12, wherein the bump is disposed on the first power pad and the second power pad.

14. A semiconductor device, comprising:
a core area comprising a cell area;
a pad area surrounding the core area;
a plurality of insulating layers in the pad area;
a plurality of power lines between the plurality of insulating layers; and
a plurality of alignment marks on the uppermost power line among the plurality of power lines,
wherein the uppermost power line comprises:
a first power line disposed adjacent to the core area; and
a second power line disposed farther from the core area than the first power line, and
wherein each of the plurality of alignment marks is configured to be electrically connected to one of the first power line and/or the second power line.

15. The semiconductor device of claim 14, wherein
each of the plurality of insulating layers comprises a via, and
the plurality of power lines are electrically connected to each other through the plurality of vias.

16. The semiconductor device of claim 14, wherein the alignment mark is disposed in at least one or more corner area of the pad area.

17. The semiconductor device of claim 14, wherein the alignment mark is disposed on one of the first power lines and the second power line, and is configured to be electrically connected to the one power line.

18. The semiconductor device of claim 14, wherein the alignment mark is disposed on the first power line and the second power line, and is configured to be electrically connected to one of the first power line and/or the second power line.

19. The semiconductor device of claim 14, wherein the alignment mark comprises a power pad, a pad open, and a bump.

20. The semiconductor device of claim 14, wherein
the alignment mark comprises a power pad, a pad open, and a bump,
the uppermost insulating layer among the plurality of insulating layers comprises the pad open,
the power pad is a part of one of the first power line and the second power line,
the pad open is located on the power pad, and
the bump is configured to contact the power pad through the pad open.
